(19) United States
(12) Patent Application Publication
(10) Pub. No.: US 2006/0244370 A1
(43) Pub. Date: Nov. 2, 2006

(54) Light-emitting layer spacing in tandem OLED devices

(75) Inventors: Yuan-Sheng Tyan, Webster, NY (US); Giuseppe Farruggia, Webster, NY (US)

Correspondence Address: Pamela R. Crocker;Patent Legal Staff, Eastman Kodak Company, 343 State Street, Rochester, NY, 14650-2201, US

(73) Assignee: Eastman Kodak Company

(21) Appl. No.: 11/119,671

(22) Filed: May 2, 2005

(51) Int. Cl. H01L 51/00

(52) U.S. Cl. 313/506

(57) ABSTRACT

A tandem organic electroluminescent device includes an anode and a cathode. The device also includes a plurality of organic electroluminescent units disposed between the anode and the cathode, wherein each of the organic electroluminescent units includes one or more organic layers including at least a light-emitting layer and an associated light-emitting junction, connecting unit disposed between adjacent organic electroluminescent units, and wherein at least two of the neighboring light-emitting junctions are separated by a distance of less than 90 nanometers.

### CROSS-REFERENCE TO RELATED APPLICATION

Reference is made to commonly assigned U.S. patent application Ser. No. 10/437,195 filed May 13, 2003 by Liang-Sheng L. Liao et al., entitled “Cascaded Organic Electroluminescent Device Having Connecting Units With n-Type and p-Type Organic Layers” (U.S. Patent Application Publication 2004/0227460 A1), the disclosure of which is herein incorporated by reference.

### FIELD OF INVENTION

The present invention relates to providing a plurality of organic electroluminescent (EL) units to form a tandem organic electroluminescent device.

### BACKGROUND OF THE INVENTION

Organic electroluminescent (EL) devices or organic light-emitting devices (OLEDs) are electronic devices that emit light in response to an applied potential. The structure of an OLED includes, in sequence, an anode, an organic EL medium, and a cathode. The organic EL medium disposed between the anode and the cathode commonly includes an organic hole-transporting layer (HTL) and an organic electron-transporting layer (ETL). Holes and electrons recombine and emit light in the ETL near the interface of HTL/ETL. Tang et al., “Organic Electroluminescent Diodes”, Applied Physics Letters, 51, 913 (1987), and commonly assigned U.S. Pat. No. 4,769,292, demonstrate highly efficient OLEDs using such a layer structure. Numerous OLEDs with alternative layer structures have been disclosed. For example, there are three-layer OLEDs that contain an organic light-emitting layer (LEL) between the HTL and the ETL, such as that disclosed by Adachi et al., “Electroluminescence in Organic Films with Three-Layer Structure”, Japanese Journal of Applied Physics, 27, L269 (1988), and by Tang et al., “Electroluminescence of Doped Organic Thin Films”, Journal of Applied Physics, 65, 3610 (1989). The LEL commonly includes a host material doped with a guest material, wherein the layer structures are denoted as HTL/LEL/ETL. Further, there are other multilayer OLEDs that contain a hole-injecting layer (HIL), or an electron-injecting layer (EIL), or a hole-blocking layer, or an electron-blocking layer in the devices. These structures have further resulted in improved device performance.

Moreover, in order to further improve the performance of the OLEDs, an OLED structure called stacked OLED (or tandem OLED), is fabricated by stacking several individual OLEDs vertically. Forrest et al. in U.S. Pat. No. 5,703,436 and Burrows et al. in U.S. Pat. No. 6,274,980 disclose their stacked OLEDs. These stacked OLEDs are fabricated by vertically stacking several OLEDs, each independently emitting light of a different color or of the same color. They believe that by using their stacked OLED structure, full color emission devices with higher integrated density in the display can be made. However, each OLED unit in their devices needs a separate power source. In an alternative design, a tandem OLED (or stacked OLED, or cascaded OLED) structure, which is fabricated by stacking several individual OLEDs vertically and driven by only a single power source, has been fabricated (see U.S. Pat. Nos. 6,337,492, 6,107,734, 6,717,358, U.S. Patent Publications 2003/0170491 A1, 2003/0189401 A1, and JP Patent Publication 2003-045676). In a tandem OLED having a number of N (N>1) EL units, the luminous efficiency can be N times as high as that of a conventional OLED containing only one EL unit (the drive voltage can also be N times as high as that of the conventional OLED). Therefore, in one aspect to achieve long lifetime, the tandem OLED needs only about 1/N of the current density used in the conventional OLED to obtain the same luminance, although the lifetime of the tandem OLED will be about N times that of the conventional OLED. In the other aspect to achieve high luminance, the tandem OLED needs only the same current density used in the conventional OLED to obtain a luminance N times as high as that of the conventional OLED while maintaining about the same lifetime. These tandem OLED devices, however, have a problem of high operating voltage, not only because the voltage of all the individual EL units adds up, but because of the large thickness of all the layers used. These devices also suffer high angle dependence in their output. It also has been difficult to include white light-emitting units in a tandem OLED structure.

### SUMMARY OF THE INVENTION

It is an object of the present invention to provide a tandem OLED that operates more effectively.

This object is achieved by a tandem organic electroluminescent device comprising:

a) an anode;

b) a cathode;

c) a plurality of organic electroluminescent units disposed between the anode and the cathode, wherein each of the organic electroluminescent units includes one or more organic layers including at least a light-emitting layer and an associated light-emitting junction;

d) a connecting unit disposed between adjacent organic electroluminescent units; and

e) wherein at least two of the neighboring light-emitting junctions are separated by a distance of less than 90 nanometers.

### ADVANTAGES OF THE INVENTION

An advantage of the present invention is that it enables a reduction of the layer thickness used in constructing a tandem OLED device resulting in a lower operating voltage.

Another advantage of the present invention is that it enables light-emitting junctions to be placed near optimum light extraction locations and thereby improves light output.

A further advantage of the present invention is that it reduces the angular dependence of light output.

Another advantage of the present invention is that the tandem OLED has an improved performance if one of more of the organic EL units emit white light.

A still further advantage of the present invention is that it permits adjustment of the output color by mixing appropriate organic EL units for different color emissions.

Another advantage of the present invention is that high efficiency white electroluminescence can be produced.

A still further advantage of the present invention is that the tandem OLED can be combined with a light extraction enhancement technique and be effectively used as an illumination device.

### BRIEF DESCRIPTION OF THE DRAWINGS

FIG. 1 shows a tandem OLED device in accordance with the present invention;

FIG. 2 shows the calculated normal angle light output plotted against the distance of the emitting junction from the reflecting electrode;

FIG. 3 shows the calculated normal angle light output for blue, green, and red light plotted against the distance of the emitting junction from the reflecting electrode;

FIG. 4 shows the calculated total (mode-1+mode-2) 540 nm light integrated over all angles plotted against the distance of the emittingjunction from the reflecting electrode; and

FIG. 5 shows the calculated dependence of the CIE color coordinates of the emitted light with angle of an OLED device having a broadband light-emitting junction placed near the M=0 anti-node location and that of another OLED device having a broadband light-emitting junction placed near the M=1 anti-node location.

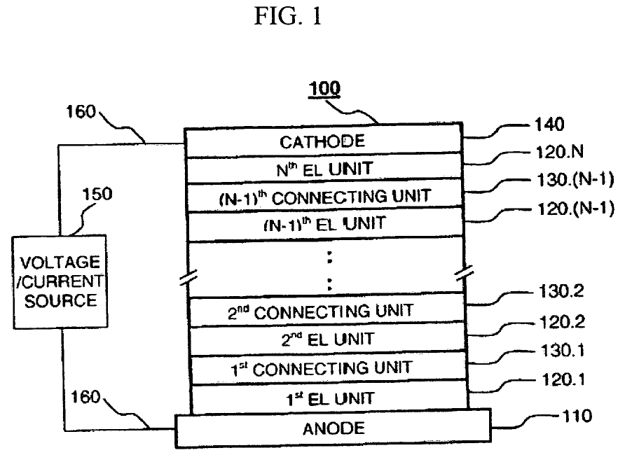

It will be understood that FIG. 1 is not to scale since the individual layers are too thin and the thickness differences of various layers too great to permit depiction to scale.

### DETAILED DESCRIPTION OF THE INVENTION

FIG. 1 shows a tandem OLED 100 in accordance with the present invention. This tandem OLED has an anode 110 and a cathode 140, at least one of which is transparent. Disposed between the anode and the cathode are N organic EL units 120, where N is an integer greater than 1. These organic EL units, connected serially to each other and to the anode and the cathode, are designated 120.1 to 120.N where 120.1 is the first EL unit (adjacent to the anode) and 120.N is the N^{th} unit (adjacent to the cathode). The term EL unit 120 represents any of the EL units named from 120.1 to 120.N in the present invention. When N is greater than 2, there are organic EL units not adjacent to the anode or cathode, and these can be referred to as intermediate organic EL units. Disposed between any two adjacent organic EL units is a connecting unit 130. There are a total of N−1 connecting units associated with N organic EL units and they are designated 130.1 to 130.(N-1). Connecting unit 130.1 is disposed between organic EL units 120.1 and 120.2, and connecting unit 130.(N-1) is disposed between organic EL units 120.(N-1) and 120.N. The term connecting unit 130 represents any of the connecting units named from 130.1 to 130.(N-1) in the present invention. The tandem OLED 100 is externally connected to a voltage/current source 150 through electrical conductors 160.

Tandem OLED 100 is operated by applying an electric potential produced by a voltage/current source 150 between a pair of contact electrodes, anode 110 and cathode 140, such that anode 110 is at a more positive potential with respect to the cathode 140. This externally applied electrical potential is distributed among the N organic EL units in proportion to the electrical resistance of each of these units. The electric potential across the tandem OLED causes holes (positively charged carriers) to be injected from anode 110 into the 1^{st} organic EL unit 120.1, and electrons (negatively charged carriers) to be injected from cathode 140 into the N^{th} organic EL unit 120.N. Simultaneously, electrons and holes are produced in, and separated from, each of the connecting units (130.1-130.(N-1)). Electrons thus produced in, for example, connecting unit 130.(N-1) are injected towards the anode and into the adjacent organic EL unit 120.(N-1). Likewise, holes produced in the connecting unit 130.(N-1) are injected towards the cathode and into the adjacent organic EL unit 120.N. Subsequently, these electrons and holes recombine in their corresponding organic EL units to produce light, which is observed via the transparent electrode or electrodes of the OLED. In other words, the electrons injected from the cathode are energetically cascading from the N^{th} organic EL unit to the 1^{st} organic EL unit, and emit light in each of the organic EL units.

Each organic EL unit 120 in the tandem OLED 100 is capable of supporting hole and electron-transport, and electron-hole recombination to produce light. Each organic EL unit 120 can include a plurality of layers including HTL (hole transport layer), ETL (electron transport layer), LEL (light-emitting layer), HIL (hole injection layer), and EIL (electron injection layer). A light-emitting layer (LEL) can include one or more sublayers each emitting a different color. These sublayers can transport predominately electrons or predominately holes. There are many organic EL multilayer structures known in the art that can be used as the organic EL unit of the present invention. These include HTL/ETL, HTL/LEL/ETL, HIL/HTL/LEL/ETL, HIL/HTL/LEL/ETL/EIL, HIL/HTL/electron-blocking layer or hole-blocking layer/LEL/ETL/EIL, HIL/HTL/LEL/hole-blocking layer/ETL/EIL. Each organic EL unit in the cascaded OLED can have the same or different layer structures from other organic EL units. The layer structure of the 1^{st} organic EL unit adjacent to the anode preferably is of HIL/HTL/LEL/ETL, the layer structure of the N^{th} organic EL unit adjacent to the anode preferably is of HTL/LEL/ETL/EIL, and the layer structure of the intermediate organic EL units preferably is of HTL/LEL/ETL. In any of the EL units, light-emitting junction can be defined as the interface between a predominately electron-transporting layer or sublayer and a predominately hole-transporting layer or sublayer. Most of the light emitted by the OLED is emitted close to the light-emitting junction.

The organic layers in the organic EL unit 120 can be formed from small molecule OLED materials or polymeric LED materials, both known in the art, or combinations thereof. The corresponding organic layer in each organic EL unit in the tandem OLED can be the same or different from other corresponding organic layers. Some organic EL units can be polymeric and other units can be of small molecules.

Each organic EL unit can be selected in order to improve performance or achieve a desired attribute, for example, light transmission through the OLED multilayer structure, driving voltage, luminance efficiency, light emission color, manufacturability, and device stability.

The number of organic EL units in the tandem OLED is, in principle, equal to or more than 2. Preferably, the number of the organic EL units in the tandem OLED is such that the luminance efficiency in units of cd/A is improved or maximized. For lamp applications, the number of organic EL units can be determined according to the maximum voltage of the power supply.

The connecting unit provides electron injection into the electron-transporting layer and hole injection into the hole-transporting layer of the two adjacent organic EL units. Preferably, the connecting unit is transparent to the light emitted by the tandem OLED device. Also preferably, the connecting unit should not have high in-plane electrical conductivity in order to prevent cross talk if the tandem OLED device is to be used in a pixilated display device or a segmented lighting device. The construction of such a connecting unit capable of providing effective electron and hole injection has also been disclosed in commonly assigned U.S. Pat. No. 6,872,472 to Liang-Sheng L. Liao et al. Most frequently, the connecting unit is constructed of two thin layers of materials, one capable of electron injecting and the other capable of hole injecting. The two thin layers of materials are selected so that electrons and holes can transport between them without impediment. These materials can be organic or inorganic. Materials such as vanadium oxide, tungsten oxide, and organic materials doped with p-type dopant such as F4-TCNQ or FeCl₃ have been used as the hole-injecting part of the connecting unit; materials such as the alkaline or alkaline-earth metal doped organic has been used as the electron injecting part of the connecting unit (Chang et al., Japanese Journal of Applied Physics 43, 9a, 6418 [2004]; Liao et al. Applied Physics Letters 84, 167 [2004]; Matsumoto et al. IDMC'03 p. 413 [2003]).

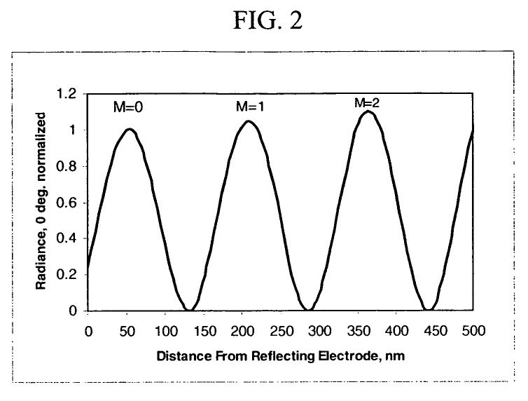

An OLED device, and especially a tandem OLED device, includes a plurality of layers with different optical indexes and there are many interfaces between these layers. Whenever there is an optical index difference between two neighboring materials, a light reflecting interface is formed. As a result, there are many light reflecting interfaces within an OLED device and light emitted from the organic EL unit experiences multiple reflections and interference events before it is emitted into the air. In particular, the interference between the light that emits directly from the organic EL unit and that reflects from the reflecting electrode has the strongest effect on the eventual output from the OLED device. FIG. 2 shows the calculated normal angle radiance output from an OLED device as a function of the distance between the light-emitting junction and the reflecting electrode. The calculation is based on a hypothetical OLED structure including a monochromatic 540 nm green light-emitting junction located between a transparent ITO electrode on glass and a reflecting Ag electrode. The total organic layer thickness was assumed to be 600 nm between the two electrodes and the optical index of the organic layer was assumed to be 1.7. The calculated radiance output is plotted against the distance between the light-emitting junction and the reflecting electrode. The radiance output oscillates strongly as this distance is changed due to constructive and destructive interferences between the light that is emitted from the organic EL unit and the light that is reflected from the Ag reflecting electrode.

The locations where the radiance output shows a local maximum can be expressed by the formula
2 nL+Qₘλ/2π=Mλ Eq. 1
wherein:

n is the refractive index and L is the distance between the light-emitting junction and the Ag reflecting electrode;

Qₘ is the phase shift in radians at the organic layer-reflecting electrode interface;

λ is the wavelength of the emitted light; and

M is the order of interference and is a non-negative integer. Qₘ can either be calculated based on the refractive index of both the electrode material and the contacting organic material or estimated experimentally. These local output maximum locations are frequently referred to as the anti-nodes of the interference. Thus the first maximum with the smallest distance between the light-emitting junction and the reflecting electrode in FIG. 2 is referred to as the M=0 anti-node, corresponding to M=0 in Eq. 1; the second one the M=1 anti-node, corresponding to M=1 in Eq. 1; and so on. In real OLED devices there can be a multiplicity of organic and inorganic sublayers between the light-emitting junction and the reflecting electrode. In these cases, the first term in Eq. 1 can be replaced by 2 ΣnᵢLᵢ, where nᵢ is the optical index and Lᵢ is the thickness of the i^{th} sublayer, respectively, and the sum is over all the sublayers between the light-emitting junction and the reflecting electrode.

Commonly assigned U.S. patent application Ser. No. 10/437,195 filed May 13, 2003 by Liang-Sheng L. Liao et al., entitled “Cascaded Organic Electroluminescent Device Having Connecting Units With N-Type And P-Type Organic Layers” (U.S. Patent Application Publication 2004/0227460 A1), the disclosure of which is herein incorporated by reference, teaches that each organic EL unit in a tandem OLED device is preferably placed at a different anti-node location. According to Eq. 1, the optical spacing, equal to the physical spacing times the optical index of the material between any two neighboring anti-nodes, is λ/2. Since most organic materials have an optical index between 1.5 and 2.2 and since the OLED operates in the visible wavelength range of 400-800 nm, Liao et al. further teaches that spacing between two neighboring emitters has to be larger than about 90 nm. For the OLED device used for calculating FIG. 1, the preferred spacing according to this teaching is close to about 150 nm.

Although the teaching of Liao et al. is effective in increasing the normal angle output of certain tandem OLED devices, it does have some shortcomings. First of all, the large spacing (>90 nm) between the organic electroluminescent units results in a thicker OLED device. Since the organic layers have limited electrical conductivity, a thicker OLED device has a higher operating voltage, which is highly undesirable for most applications.

Second, the method works the best for an OLED device that emits only narrowband light. For the purpose of the present invention, a narrowband light is defined as a light having an emission radiance spectrum having less than 150 nm bandwidth measured at 10% of the peak height, and a broadband emission is defined as having the bandwidth measured at 10% of the peak height larger than 150 nm at 10% of peak height. The term white emission and broadband emission will be used interchangeably in the present application. For the purpose of the present invention, a blue emission is defined as a narrowband light that peaks in the blue region of the spectrum, <500 nm in wavelength; a blue-rich emission is defined as a broadband light that has more than 50% of the radiance energy in the blue wavelength region less than 500 nm in wavelength. Similarly, a green emission is a narrowband emission that peaks between 500 nm and 600 nm, a green-rich emission is a broadband light that has more than 50% of its radiance energy between 500 nm and 600 nm, a red emission is a narrowband emission that peaks above 600 nm, and a red-rich emission is a broadband light with more than 50% of its radiance energy above 600 nm.

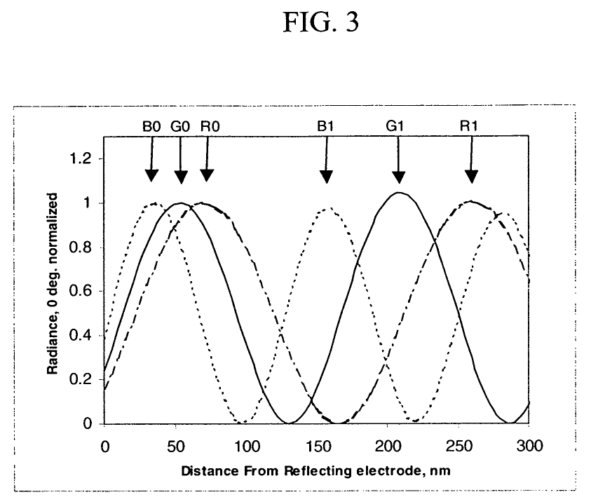

As can be seen from Eq. 1, the location of the anti-nodes is a function of the wavelength, λ. FIG. 3 shows the output of the blue, green, and red color lights of wavelength 460 nm, 540 nm, and 620 nm, respectively, plotted against the distance from the reflecting electrode. In this figure, B0, G0, and R0 denote the M=0 order and B1, G1, and R1 denote the M=1 order anti-nodes of the blue, green, and red lights, respectively. The anti-nodes for the different color lights of the same order are at different locations. The separation between the anti-nodes of the same order for the different color lights increases with increasing M. Even for M=1, at the anti-node of one of the colors the outputs of the other two color lights are almost at their minimum. Since a broadband emission covers a wide spectrum of light, no matter where a broadband emitting junction is placed, there is always some reductions in output of some of the colors. There is no obvious optimum location for a broadband emitting-junction to be placed at the higher order anti-node locations. The teaching of Liao et al. does not provide an effective method to construct a white light-emitting tandem OLED devices using broadband emitters.

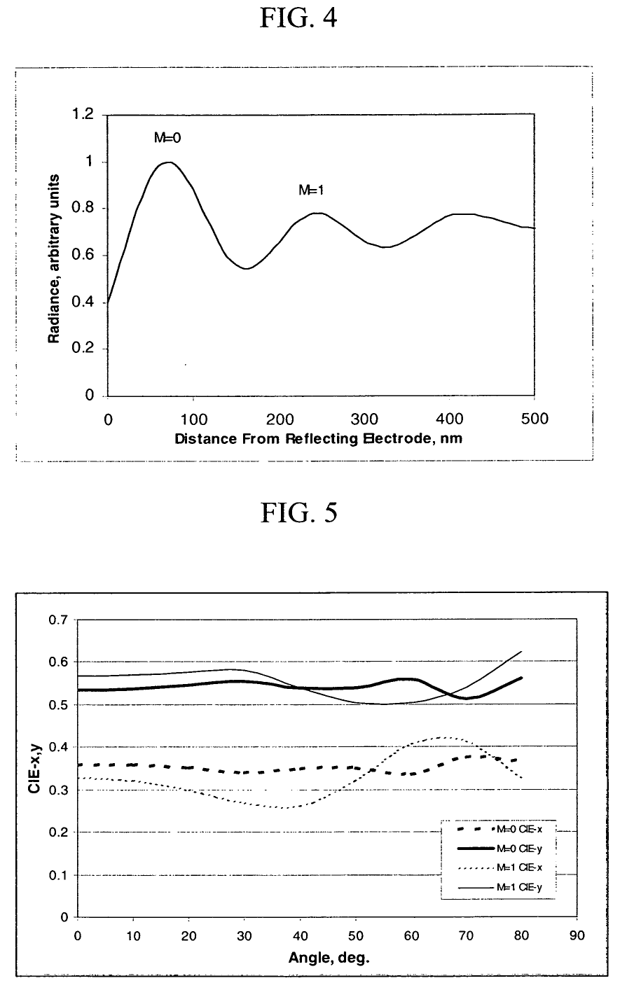

Third, it has been well known to those skilled in the art that, because of the high index of the light-emitting materials used, only a small fraction of the produced light (hereto referred to as the mode-1 light) is emitted into the air to serve useful functions in a typical OLED device. The remainder of the produced light is trapped in the substrate (hereto referred to as the mode-2 light) or the organic and anode layers (hereto referred to as the mode-3 light) due to total internal reflection. These trapped lights are eventually absorbed by the electrode or the organic layers. Eq. 1 is a description of mode-1 light emitted at the normal angle from the OLED device, and this portion of light is the most important to display applications. There are other applications of OLED devices, such as those for illumination purposes, where the total light output integrated over all angles is important and in some of these devices a scattering layer or other extraction enhancing technique is used to also extract a part of the mode-2 light into the air. For these devices, the total mode-1 and mode-2 light integrated over all angles is the quantity that needs to be maximized. FIG. 4 shows the calculated, angular-integrated mode-1 plus mode-2 light as a function of the distance between the light-emitting junction and the reflecting electrode. The device structure used for this calculation is the same as the one used to calculate FIG. 2.

When compared with FIG. 2, FIG. 4 shows that the location of all the anti-nodes moves farther away from the reflecting electrode, the height of the emission peaks is the largest for M=0, all the higher order peaks have lower heights, and the magnitude of the oscillation in light output due to interference is reduced. If a tandem OLED device is made following the teaching of Liao et al., the first emitting junction will be placed at the M=0 anti-node location and the second emitting junction will be placed at the M=1 anti-node location. Because of the lower output of the M=1 peak relative to the M=0 peak, the total output of the tandem OLED will be lower than twice the single stack OLED device using the same light-emitting unit. The voltage output of the stacked device will also be higher because of the large spacing between the two light-emitting junctions. Furthermore, for OLED devices that use a scattering layer or some other way to extract the mode-3 light as well, it can be shown that the light output integrated over all angles has little or no oscillations as the distance between the light-emitting junction and the reflecting electrode is varied. The teaching of Liao et al. is an unnecessary constraint in the placement of the light-emitting junctions.

Fourth, the angular dependence of light output increases with increasing distance between the emitting junction and the reflecting electrode. FIG. 5 shows the calculated dependence of the CIE color coordinates of the emitted light with angle of an OLED device having a broadband light-emitting junction placed near the M=0 anti-node location and that of another OLED device having a broadband light-emitting junction placed near the M=1 anti-node location. For this calculation, a “quantum white” emitter having an equal number of photons over a wavelength range between 380 nm and 780 nm was used and the anti-node locations refer to those for a 540 nm wavelength light. The device that had the emitting junction at the M=1 anti-node location clearly showed much more variation in color with angle than the one with the emitting junction at the M=0 anti-node location. The teaching of Liao et al. places at least one light-emitting junction at M=1 or higher locations and hence will result in a stacked OLED device with an output that depends strongly on angle.

In accordance with the present invention, a tandem OLED device including two or more organic electroluminescent units is constructed having at least two of the light-emitting junctions located less than 90 nm apart. Because of the small spacing between them, the two light-emitting junctions can both be near a same anti-node location. Most preferably, they are both located near the M=0 location. The M=0 location is about 50 nm from the reflecting electrode for a green emitting light of about 540 nm wavelength in a device having a Ag reflecting electrode and organic layers with about 1.7 index of refraction. For emitting light of other wavelengths and devices with other reflectors and organic indexes, the M=0 location can be calculated using Eq. 1. For a broadband, or white, light-emitting layer the M=0 location for the green light is an effective approximation for the entire spectrum. Preferably, at least one of the light-emitting junction is located less than 90 nm from the reflecting electrode. The device in accordance with this embodiment of the present invention has smaller thickness than a comparative prior art device having the same number of organic electroluminescent units and therefore lower operating voltage and smaller angular dependence of its output.

In another embodiment of the present invention, a stacked OLED device including two narrow band emitting organic electroluminescent units is constructed such that one of the light-emitting junctions is located slightly closer to the reflecting electrode than the M=0 anti-node, and the other light-emitting junction is placed slightly farther away from the reflecting electrode than the M=0 anti-node. By keeping the spacing between the two light-emitting junctions small, both emitters are near the M=0 anti-node. For example, if the emission of the electroluminescent units is green light peaking at about 540 nm wavelength and the reflecting electrode is made of Ag, the M=0 anti-node is about 50 nm from the reflecting electrode. The 1^{st} light-emitting junction can be placed at about 30 nm from the reflecting electrode and the 2^{nd} junction about 80 nm from the reflecting electrode. Both emitters are expected to produce a large fraction of the normal angle output that would have been produced if the light-emitting junctions were to be placed at the M=0 and M=1 anti-node locations, respectively. Although there is some reduction in light output, the device according to the present invention is 130 nm thinner than the device that has the second emitting junction located at the 2^{nd} anti-node. The device operating voltage is expected to be substantially lower and the benefit of the lowered voltage can outweigh the loss in light output. Furthermore, since both emitters are located closer to the reflecting electrode, the angular dependence of light output is much reduced.

In another embodiment of the present invention a two-stack tandem OLED including two broadband light-emitting units is constructed with the first light-emitting junction placed slightly closer to the reflecting electrode than the M=0 anti-node of a 540 nm green light, and the second junction placed at location B, slightly farther away from the reflecting electrode than the M=0 anti-node of a 540 nm green light. Since the location of the anti-nodes is wavelength dependent, the 540 nm wavelength represents a reasonable compromise for the wide spectrum of the emitter. By keeping the spacing between the two light-emitting junctions small, both emitters are near the M=0 anti-node of all the wavelengths. In the case illustrated, the 1^{st} light-emitting junction is placed at about 30 nm from the reflecting electrode and the 2^{nd} junction about 80 nm from the reflecting electrode. Both emitters are expected to produce a large fraction of the normal angle output that would have been produced if a light-emitting junction were to be placed at the M=0. In comparison with the device in accordance with the teaching of Liao et al., the device operating voltage is expected to be substantially lower. Furthermore, since the location of the M=1 anti-node depends greatly on wavelength, a device in accordance with the teaching of Liao et al. would have to place the second emitter at a location that is the anti-node of only one of the wavelengths and the output of the other wavelengths will be greatly diminished. In addition, since both emitters in accordance with the present invention are located closer to the reflecting electrode, the angular dependence of light output is much reduced.

In accordance with another embodiment of the present invention a tandem OLED device can include two broadband emitting organic electroluminescent units with different emission spectra, one is blue or blue-rich and the other one is red or red-rich. The blue or blue-rich light-emitting junction is located near the M=0 anti-node of the blue light, and the red-rich light-emitting junction is located near the M=0 anti-node of the red light. For example, if a Ag reflecting electrode is used and the optical index of the organic layers is about 1.7, the M=0 anti-node of the 450 nm blue light and that of the 650 nm red light are located about 35 nm and 70 nm, respectively, from the reflecting electrode. Placing the blue-rich light-emitting junction at 30 nm and the red rich light-emitting junction at 80 nm will increase the light output from both junctions. It is again possible to also achieve the benefits of the lowered voltage and reduced angular dependence.

In another embodiment of the present invention, a tandem OLED device having three organic electroluminescent units is constructed by placing two light-emitting units near the M=0 anti-node, as described in the previous embodiment, and the third light-emitting unit near the M=1 anti-node location. The individual organic electroluminescent unit can be narrowband or broadband. The light-emitting junction of the narrowband units is placed near the anti-nodes of the corresponding colors. For the broadband units, the light-emitting junction can be placed near the anti-node of the green light as a compromise. Alternatively, the broadband units can be blue-rich, green-rich or red-rich and be placed near the anti-nodes of the corresponding color that they are rich in.

For the purpose of the present invention a light-emitting junction is defined as being near an anti-node location when it is less than 50 nm away from the location.

In another embodiment of the present invention, a broadband-emitting tandem OLED device having four or more organic electroluminescent units is constructed. Two of the light-emitting junctions are placed near the M=0 location and at least two of the remaining light-emitting junctions are placed near the M=1 locations of different colors. The location of the M=1 anti-nodes can be calculated for different colors using Eq. 1. For the device using n=1.7 organics and Ag reflecting electrode, the M=1 anti-node for the 450 nm blue light, the 550 nm green light, and the 650 nm red light are located at about 160 nm, 210 nm, and 260 nm, respectively from the reflecting electrode. For example, two light-emitting junctions with balanced white spectra can be placed at 30 nm and 80 nm from the reflecting electrode, respectively. A third light-emitting junction with a blue or blue-rich white spectrum can be located about 160 nm from the reflecting electrode. A fourth light-emitting junction with a red or red-rich spectrum can be placed about 260 nm from the reflecting electrode. A fifth light-emitting junction with green or green-rich white spectrum can be placed about 210 nm from the reflecting electrode. This method can be readily extended for devices having more organic-electroluminescent units or other combinations of organic-electroluminescence units.

In another embodiment of the present invention, a broadband emitting tandem OLED device is constructed. This device is commonly referred to as a bottom-emitting device. The device includes, in the following order: a substrate; a transparent or semi-transparent electrode; a reflecting electrode; a plurality of organic electroluminescent units disposed between the transparent or semitransparent electrode and the reflecting electrode; a connecting unit disposed between adjacent organic electroluminescent units, and a light-extraction enhancement layer disposed between the substrate and the reflecting electrode, wherein each of the organic electroluminescent units includes one or more organic layers including at least a light-emitting layer and an associated light-emitting junction, and wherein the distance between at least two of the neighboring light-emitting junctions is less than 90 nanometers. The extraction enhancement layer is most preferably a scattering layer and is optically connected to at least of the light-emitting layers in the organic EL units. For this disclosure, one layer is defined as optically connected to another layer when there is no material between these two layers that has an optical index less than the smallest of the optical indexes of the two layers by more than 0.1. For scattering layers that include materials having scattering centers dispersed in a matrix, the index of the matrix material is used in this definition. For example, if a scattering layer includes a dispersion of titanium-oxide particles dispersed in polymer matrix having an optical index of 1.5, the optical index 1.5 of the polymer matrix is used to determine whether the scattering layer is optically connected to at least one of the light-emitting layers. If there exists a material having an optical index of less than 1.4 disposed between the scattering layer and the light-emitting layer, than the scattering layer is considered to be not optically connected to the light scattering layer. Furthermore, if the optical index of the matrix material in the scattering layer is smaller than that of the light-emitting layer, it is preferably to have at least a fraction of the scattering centers in the scattering layer located less than or equal to about 1 micrometer from the surface of the scattering layer closest to the light-emitting layer. This is to facilitate the evanescent coupling of the emitted light to the scattering centers to improve the scattering efficiency.

The light-extraction enhancement layer can be disposed between the substrate and the transparent or semi-transparent electrode, between the transparent or semi-transparent electrode and the organic EL units, between two of the organic EL units, or between the organic units and the reflecting electrode. As is well known in the art, in a typical prior art bottom-emitting OLED structure, because the index of the light-emitting layers is high, typically higher than 1.6, a large fraction of the light produced is trapped inside the organic EL units (hereafter referred to as the mode-3 light) or the substrate (hereafter referred to as the mode-2 light), and only a small fraction (the mode-1 light) can actually emitted into the air and perform useful functions. The light-extraction enhancement layer in the present invention permits some of the mode-2 and mode-3 light to be extracted into the air. Furthermore, because the light-extraction enhancement layer, especially in the form of a scattering layer, randomizes the angle of the emitted light, the oscillation of light output intensity with the distance between the light-emitting junction and the reflecting electrode is mostly reduced and the light-emitting junctions do not have to be restricted to the anti-node locations. This permits the junctions to be placed closer to each other than taught in the prior art to reduce the voltage needed to drive the device.

In another embodiment of the present invention, a broadband emitting tandem OLED device is constructed. This device is commonly referred to as a top-emitting device. The device includes, in the following order: a substrate; a reflecting electrode; a transparent or semitransparent electrode; a plurality of organic electroluminescent units disposed between the reflecting electrode and the transparent or semitransparent electrode; a connecting unit disposed between adjacent organic electroluminescent units; and a light-extraction enhancement layer disposed over the reflecting electrode, wherein each of the organic electroluminescent units includes one or more organic layers including at least a light-emitting layer and an associated light-emitting junction, and wherein the distance between at least two of the neighboring light-emitting junctions is less than 90 nanometers. The light is emitted through the transparent or semitransparent electrode. The light-extraction enhancement layer can be disposed between the reflecting electrode and the organic EL units, between two of the organic EL units, between the organic units and the transparent or semitransparent electrode, or over the transparent or semitransparent electrode. There can be other layers such as a dielectric layer, or a polymer layer, or both disposed over the transparent or semitransparent electrode. The light-extraction enhancement layer can be disposed over these other layers as long as the light-extraction enhancement layer is optically connected to at least one of the light-emitting layers. The light-extraction enhancement layer is most preferably a scattering layer. As is well known in the art, in a typical prior art top-emitting OLED structure, because the index of the light-emitting layers is high, typically higher than 1.6, a large fraction of the light produced by the light-emitting units is trapped inside the organic EL unit (hereafter referred to as the mode-3 light) or the substrate (hereafter referred to as the mode-2 light), and only a small fraction (the mode-1 light) can actually emitted into the air. The light-extraction enhancement layer permits some of the mode-2 and mode-3 light to be extracted into the air. Furthermore, because the light-extraction enhancement layer, especially in the form of a scattering layer, can randomize the angle of the light emission, the oscillation of light output intensity with the distance between the light-emitting junction and the reflecting electrode is mostly reduced and the light-emitting junctions do not have to be restricted to the anti-node locations. If the tandem OLED device is intended for high-resolution pixilated display applications, it is important to keep the total thickness of all the layers above the reflecting electrode thin, at least thinner than the smaller linear dimension of the individual pixels in the display device, which is commonly about 0.1 mm in dimension. The top-emitting tandem OLED device can include a coversheet to protect the device from the environment or from mechanical abuse. When a coversheet is used, it is important to include an optical isolation layer between the coversheet and the light-extraction enhancement layer. The optical isolation layer is a transparent layer having an optical index at least 0.1 smaller than the smaller of the optical indexes of the coversheet and the light-emitting layers. The thickness of the optical isolation layer needs to be at least 1 μm and preferably more than 5 μm. For example, if the index of the coversheet is 1.5 and that of the light-emitting layers is 1.7, the index of the optical isolation layer needs to be 1.4 or smaller. Preferably, an air gap is used as the optical isolation layer. For the purpose of this disclosure the air gap is broadly defined as a space that can contain vacuum, air, nitrogen, or any other gases. The coversheet is a made of a material that is essentially transparent to the light emitted from the tandem OLED device. Typical materials include glass and polymer materials.

In another embodiment of the present invention, a broadband emitting tandem OLED device is constructed. The device includes a substrate and, on the first surface of the substrate, an anode, a cathode, a plurality of organic electroluminescent units disposed between the anode and the cathode, a connecting unit disposed between adjacent organic electroluminescent units, and a light-extraction enhancement layer disposed over the second surface of the substrate, wherein each of the organic electroluminescent units includes one or more organic layers including at least a light-emitting layer and an associated light-emitting junction, and wherein the distance between at least two of the neighboring light-emitting junctions is less than 90 nanometers. The light-extraction enhancement layer is preferably a scattering layer. Most preferably the scattering layer includes scattering centers dispersed in a matrix having an optical index equal to or smaller than that of the substrate and the scattering layer has at least a fraction of the scattering centers located less than one micrometer from interface between the scattering layer and the substrate.

White light-emitting tandem OLED devices as constructed in accordance with the present invention can be used for illumination or lighting applications, or they can be used in combination with color filters or microcavity structures or other color selection techniques for display applications.

Substrate

The tandem OLED of the present invention is typically provided over a supporting substrate where either the cathode or anode can be in contact with the substrate. The electrode in contact with the substrate is conveniently referred to as the bottom electrode. Conventionally, the bottom electrode is the anode, but the present invention is not limited to that configuration. The substrate can either be light transmissive or opaque, depending on the intended direction of light emission. The light transmissive property is desirable for viewing the EL emission through the substrate. Transparent glass or plastic is commonly employed in such cases. For applications where the EL emission is viewed through the top electrode, the transmissive characteristic of the bottom support is immaterial, and therefore can be light transmissive, light absorbing or light reflective. Substrates for use in this case include, but are not limited to, glass, plastic, semiconductor materials, silicon, ceramics, and circuit board materials. It can be necessary to provide in these device configurations a light-transparent top electrode.

Anode

When EL emission is viewed through anode 110, the anode should be transparent or substantially transparent to the emission of interest. Common transparent anode materials used in the present invention are indium-tin oxide (ITO), indium-zinc oxide (IZO) and tin oxide, but other metal oxides can work including, but not limited to, aluminum- or indium-doped zinc oxide, magnesium-indium oxide, and nickel-tungsten oxide. In addition to these oxides, metal nitrides such as gallium nitride, and metal selenides such as zinc selenide, and metal sulfides such as zinc sulfide, can be used as the anode. For applications where EL emission is viewed only through the cathode electrode, the transmissive characteristics of the anode are immaterial and any conductive material can be used, regardless if it is transparent, opaque or reflective. Example conductors for this application include, but are not limited to, gold, iridium, molybdenum, palladium, and platinum. Typical anode materials, transmissive or otherwise, have a work function higher than 4.0 eV. Desired anode materials are commonly deposited by any suitable way such as evaporation, sputtering, chemical vapor deposition, or electrochemical means. Anodes can be patterned using well known photolithographic processes. Optionally, anodes can be polished prior to the deposition of other layers to reduce surface roughness so as to reduce electrical shorts or enhance reflectivity.

Hole-Injecting Layer (HIL)

Although not always necessary, it is often useful to provide a HIL in the 1^{st} organic EL unit to contact the anode 110. The HIL can serve to improve the film formation property of subsequent organic layers and to facilitate injection of holes into the HTL reducing the driving voltage of the tandem OLED. Suitable materials for use in the HIL include, but are not limited to, porphyrinic compounds as described in U.S. Pat. No. 4,720,432, plasma-deposited fluorocarbon polymers as described in U.S. Pat. No. 6,208,075, and some aromatic amines, for example, m-MTDATA (4,4′,4″-tris[(3-ethylphenyl)phenylamino]triphenylamine). A p-type doped organic layer for use in the aforementioned connecting unit is also useful for the HIL as described in U.S. Pat. No. 6,423,429. Alternative hole-injecting materials reportedly useful in organic EL devices are described in EP0891 121 A1 and EP 1 029 909 A1.

Hole-Transporting Layer (HTL)

The HTL in organic EL units contains at least one hole-transporting compound such as an aromatic tertiary amine, where the latter is understood to be a compound containing at least one trivalent nitrogen atom that is bonded only to carbon atoms, at least one of which is a member of an aromatic ring. In one form the aromatic tertiary amine can be an arylamine, such as a monoarylamine, diarylamine, triarylamine, or a polymeric arylamine. Exemplary monomeric triarylamines are illustrated by Klupfel et al. U.S. Pat. No. 3,180,730. Other suitable triarylamines substituted with one or more vinyl radicals or at least one active hydrogen-containing group are disclosed by Brantley, et al. in U.S. Pat. Nos. 3,567,450 and 3,658,520.

A more preferred class of aromatic tertiary amines are those which include at least two aromatic tertiary amine moieties as described in U.S. Pat. Nos. 4,720,432 and 5,061,569. The HTL can be formed of a single or a mixture of aromatic tertiary amine compounds. Illustrative of useful aromatic tertiary amines are the following:

1,1-Bis(4-di-p-tolylaminophenyl)cyclohexane;

1,1-Bis(4-di-p-tolylaminophenyl)-4-phenylcyclohexane;

4,4′-Bis(diphenylamino)quadriphenyl;

Bis(4-dimethylamino-2-methylphenyl)-phenylmethane;

N,N,N-Tri(p-tolyl)amine;

4-(di-p-tolylamino)-4′-[4(di-p-tolylamino)-styryl]stilbene;

N,N,N′,N′-Tetra-p-tolyl-4-4′-diaminobiphenyl;

N,N,N′,N′-Tetraphenyl-4,4′-diaminobiphenyl;

N,N,N′,N′-tetra-1-naphthyl-4,4′-diaminobiphenyl;

N,N,N′,N′-tetra-2-naphthyl-4,4′-diaminobiphenyl;

N-Phenylcarbazole;

4,4′-Bis[N-(1-naphthyl)-N-phenylamino]biphenyl;

4,4′-Bis[N-(1-naphthyl)-N-(2-naphthyl)amino]biphenyl;

4,4″-Bis[N-(1-naphthyl)-N-phenylamino]p-terphenyl;

4,4′-Bis[N-(2-naphthyl)-N-phenylamino]biphenyl;

4,4′-Bis[N-(3-acenaphthenyl)-N-phenylamino]biphenyl;

1,5-Bis[N-(1-naphthyl)-N-phenylamino]naphthalene;

4,4′-Bis[N-(9-anthryl)-N-phenylamino]biphenyl;

4,4″-Bis[N-(1-anthryl)-N-phenylamino]-p-terphenyl;

4,4′-Bis[N-(2-phenanthryl)-N-phenylamino]biphenyl;

4,4′-Bis[N-(8-fluoranthenyl)-N-phenylamino]biphenyl;

4,4′-Bis[N-(2-pyrenyl)-N-phenylamino]biphenyl;

4,4′-Bis[N-(2-naphthacenyl)-N-phenylamino]biphenyl;

4,4′-Bis[N-(2-perylenyl)-N-phenylamino]biphenyl;

4,4′-Bis[N-(1-coronenyl)-N-phenylamino]biphenyl;

2,6-Bis(di-p-tolylamino)naphthalene;

2,6-Bis[di-(1-naphthyl)amino]naphthalene;

2,6-Bis[N-(1-naphthyl)-N-(2-naphthyl)amino]naphthalene;

N,N,N′,N′-Tetra(2-naphthyl)-4,4″-diamino-p-terphenyl;

4,4′-Bis {N-phenyl-N-[4-(1-naphthyl)-phenyl]amino}biphenyl;

4,4′-Bis[N-phenyl-N-(2-pyrenyl)amino]biphenyl;

2,6-Bis[N,N-di(2-naphthyl)amine]fluorene;

1,5-Bis[N-(1-naphthyl)-N-phenylamino]naphthalene; and

4,4′,4″-tris[(3-methylphenyl)phenylamino]triphenylamine.

Another class of useful hole-transporting materials includes polycyclic aromatic compounds as described in EP 1 009 041. Tertiary aromatic amines with more than two amine groups can be used including oligomeric materials. In addition, polymeric hole-transporting materials can be used such as poly(N-vinylcarbazole) (PVK), polythiophenes, polypyrrole, polyaniline, and copolymers such as poly(3,4-ethylenedioxythiophene)/poly(4-styrenesulfonate) also called PEDOT/PSS.

Light-Emitting Layer (LEL)

As more fully described in U.S. Pat. Nos. 4,769,292 and 5,935,721, the LEL in organic EL units includes a luminescent or fluorescent material where electroluminescence is produced as a result of electron-hole pair recombination in this region. The LEL can include a single material, but more commonly includes a host material doped with a guest compound or compounds where light emission comes primarily from the dopant and can be of any color. The host materials in the LEL can be an electron-transporting material, a hole-transporting material, or another material or combination of materials that support hole-electron recombination. The dopant is typically selected from highly fluorescent dyes, but phosphorescent compounds, e.g., transition metal complexes as described in WO 98/55561, WO 00/18851, WO 00/57676, and WO 00/70655 are also useful. Dopants are typically coated as 0.01 to 10% by weight into the host material. Polymeric materials such as polyfluorenes and polyvinylarylenes, e.g., poly(p-phenylenevinylene), PPV, can also be used as the host material. In this case, small molecule dopants can be molecularly dispersed into the polymeric host, or the dopant can be added by copolymerizing a minor constituent into the host polymer.

An important relationship for choosing a dye as a dopant is a comparison of the electron energy band gap. For efficient energy transfer from the host to the dopant molecule, a necessary condition is that the band gap of the dopant is smaller than that of the host material. For phosphorescent emitters it is also important that the host triplet energy level of the host be high enough to enable energy transfer from host to dopant.

Host and emitting molecules known to be of use include, but are not limited to, those disclosed in U.S. Pat. Nos. 4,768,292, 5,141,671, 5,150,006, 5,151,629, 5,405,709, 5,484,922, 5,593,788, 5,645,948, 5,683,823, 5,755,999, 5,928,802, 5,935,720, 5,935,721, and 6,020,078.

Metal complexes of 8-hydroxyquinoline (oxine) and similar derivatives constitute one class of useful host compounds capable of supporting electroluminescence. Illustrative of useful chelated oxinoid compounds are the following:
CO-1: Aluminum trisoxine [alias, tris(8-quinolinolato)aluminum(III)];
CO-2: Magnesium bisoxine [alias, bis(8-quinolinolato)magnesium(II)];
CO-3: Bis[benzo {f}-8-quinolinolato]zinc(II);
CO-4: Bis(2-methyl-8-quinolinolato)aluminum(III)-μ-oxo-bis(2-methyl-8-quinolinolato) aluminum(III);
CO-5: Indium trisoxine [alias, tris(8-quinolinolato)indium];
CO-6: Aluminum tris(5-methyloxine) [alias, tris(5-methyl-8-quinolinolato) aluminum(III)];
CO-7: Lithium oxine [alias, (8-quinolinolato)lithium(I)];
CO-8: Gallium oxine [alias, tris(8-quinolinolato)gallium(III)]; and
CO-9: Zirconium oxine [alias, tetra(8-quinolinolato)zirconium(IV)].

Other classes of useful host materials include, but are not limited to, derivatives of anthracene, such as 9,10-di-(2-naphthyl)anthracene and derivatives thereof as described in U.S. Pat. No. 5,935,721, distyrylarylene derivatives as described in U.S. Pat. No. 5,121,029, and benzazole derivatives, for example, 2,2′,2″-(1,3,5-phenylene)tris[1-phenyl-1H-benzimidazole]. Carbazole derivatives are particularly useful hosts for phosphorescent emitters.

Useful fluorescent dopants include, but are not limited to, derivatives of anthracene, tetracene, xanthene, perylene, rubrene, coumarin, rhodamine, and quinacridone, dicyanomethylenepyran compounds, thiopyran compounds, polymethine compounds, pyrilium and thiapyrilium compounds, fluorene derivatives, periflanthene derivatives, indenoperylene derivatives, bis(azinyl)amine boron compounds, bis(azinyl)methane compounds, and carbostyryl compounds.

Electron-Transporting Layer (ETL)

Preferred thin film-forming materials for use in forming the ETL in the organic EL units of the present invention are metal chelated oxinoid compounds, including chelates of oxine itself, also commonly referred to as 8-quinolinol or 8-hydroxyquinoline. Such compounds help to inject and transport electrons, exhibit high levels of performance, and are readily deposited to form thin films. Exemplary oxinoid compounds were listed previously.

Other electron-transporting materials include various butadiene derivatives as disclosed in U.S. Pat. No. 4,356,429 and various heterocyclic optical brighteners as described in U.S. Pat. No. 4,539,507. Benzazoles and triazines are also useful electron-transporting materials.

Organic Electron-Injecting Layer (EIL)

Although not always necessary, it is often useful to provide an EIL in the N-th organic EL unit to contact the cathode 140. The EIL can serve to facilitate injection of electrons into the ETL and to increase the electrical conductivity resulting in a low driving voltage of the tandem OLED. Suitable materials for use in the EIL are the aforementioned ETL's doped with strong reducing agents or low work-function metals (<4.0 eV) as described in the aforementioned n-type doped organic layer for use in the connecting units. Alternative inorganic electron-injecting materials can also be useful in the organic EL unit, which will be described in following paragraph.

Cathode

When light emission is viewed solely through the anode, the cathode 140 used in the present invention can include nearly any conductive material. Desirable materials have effective film-forming properties to ensure effective contact with the underlying organic layer, promote electron injection at low voltage, and have effective stability. Useful cathode materials often contain a low work-function metal (<4.0 eV) or metal alloy. One preferred cathode material includes a Mg:Ag alloy wherein the percentage of silver is in the range of 1 to 20%, as described in U.S. Pat. No. 4,885,221. Another suitable class of cathode materials includes bilayers including a thin inorganic EIL in contact with an organic layer (e.g., ETL), which is capped with a thicker layer of a conductive metal. Here, the inorganic EIL preferably includes a low work-function metal or metal salt, and if so, the thicker capping layer does not need to have a low work function. One such cathode includes a thin layer of LiF followed by a thicker layer of Al as described in U.S. Pat. No. 5,677,572. Other useful cathode material sets include, but are not limited to, those disclosed in U.S. Pat. Nos. 5,059,861, 5,059,862, and 6,140,763.

When light emission is viewed through the cathode, the cathode should be transparent or nearly transparent. For such applications, metals should be thin or one should use transparent conductive oxides, or includes these materials. Optically transparent cathodes have been described in more detail in U.S. Pat. Nos. 4,885,211, 5,247,190, 5,703,436, 5,608,287, 5,837,391, 5,677,572, 5,776,622, 5,776,623, 5,714,838, 5,969,474, 5,739,545, 5,981,306, 6,137,223, 6,140,763, 6,172,459, 6,278,236, 6,284,393, and EP 1 076 368. Cathode materials are typically deposited by thermal evaporation, electron-beam evaporation, ion sputtering, or chemical vapor deposition. When needed, patterning can be achieved through many well known methods including, but not limited to, through-mask deposition, integral shadow masking, for example as described in U.S. Pat. No. 5,276,380 and EP 0 732 868, laser ablation, and selective chemical vapor deposition.

Extraction Enhancement Layer

The light-extraction enhancement layer can be a light scattering layer. The light scattering layer used in the present invention can include scattering centers embedded in a matrix, or it can include textures or microstructures on a surface. The matrix of the light scattering layer can be a polymer coated as a thin-layer from a solution, from a melt, or other suitable forms. It can also be a monomer and polymerized after being coated as a thin-film by UV-light, heat, or other suitable way. Common coating techniques such as spin-coating, blade coating, and screening printing, can be appropriately selected. Alternatively, the scattering layer can be a separate element laminated to the surface of the top electrode layer or to the substrate, depending on the desired location of the scattering layer in the OLED device structure. The index of the scattering centers need to be significantly different from that of the matrix, and preferably differ by more than 5% of the index value of light-emitting layer. The scattering centers can include particles, exemplary particle materials are TiO₂, Sb₂O₃, CaO, and In₂O₃, or it can include voids or air bubbles. The size of the particles can be comparable to the wavelength of light to be scattered, and can range from several tens of nanometers to several micrometers. The thickness of the scattering layer can range from less than a micrometer to several micrometers. The thickness and the loading of particles in the matrix need to be optimized to achieve optimum light extraction from any OLED devices. In the case of scattering layers having textures or microstructures on a surface, the texture or microstructure can be micro-lenses, or they can be periodical or random structure of depth and size comparable to the wavelength to be scattered. These surface features can be produced although the scattering layer is coated, or they can be embossed after the scattering layer is coated. The scattering layer with surface scattering features can also be made separately and laminated to the OLED device.

Other Device Features

Alternative Layers

In some instances, LEL and ETL in the organic EL units can optionally be collapsed into a single layer that serves the function of supporting both light emission and electron-transportation. It is also known in the art that emitting dopants can be added to the HTL, which can serve as a host. Multiple dopants can be added to one or more layers in order to produce a white-emitting OLED, for example, by combining blue- and yellow-emitting materials, cyan- and red-emitting materials, or red-, green-, and blue-emitting materials. White-emitting devices are described, for example, in U.S. Patent Application Publication 2002/0025419 A1, U.S. Pat. Nos. 5,683,823, 5,503,910, 5,405,709, 5,283,182, EP 1 187 235, and EP 1 182 244.

Additional layers such as electron or hole-blocking layers as taught in the art can be employed in devices of the present invention. Hole-blocking layers are commonly used to improve efficiency of phosphorescent emitter devices, for example, as in U.S. Patent Application Publication 2002/0015859 A1.

Deposition of Organic Layers

The organic materials mentioned above are suitably deposited through a vapor-phase method such as thermal evaporation, but can be deposited from a fluid, for example, from a solvent with an optional binder to improve film formation. If the material is a polymer, solvent deposition is useful but other methods can be used, such as sputtering or thermal transfer from a donor sheet. The material to be deposited by thermal evaporation can be vaporized from an evaporation “boat” often includes a tantalum material, e.g., as described in U.S. Pat. No. 6,237,529, or can be first coated onto a donor sheet and then sublimed in closer proximity to the substrate. Layers with a mixture of materials can use separate evaporation boats or the materials can be premixed and coated from a single boat or donor sheet. For full color display, the pixelation of LELs can be needed. This pixelated deposition of LELs can be achieved using shadow masks, integral shadow masks (U.S. Pat. No. 5,294,870), spatially-defined thermal dye transfer from a donor sheet (U.S. Pat. Nos. 5,688,551, 5,851,709, and 6,066,357) and inkjet method (U.S. Pat. No. 6,066,357). For other organic layers either in the organic EL units or in the connecting units, pixelated deposition is not necessarily needed.

Encapsulation

Most OLEDs are sensitive to moisture or oxygen, or both, so they are commonly sealed in an inert atmosphere such as nitrogen or argon, along with a desiccant such as alumina, bauxite, calcium sulfate, clays, silica gel, zeolites, alkaline metal oxides, alkaline earth metal oxides, sulfates, or metal halides and perchlorates. Methods for encapsulation and desiccation include, but are not limited to, those described in U.S. Pat. No. 6,226,890. In addition, barnier layers such as SiOx, Teflon, and alternating inorganic/polymeric layers are known in the art for encapsulation.

The invention has been described in detail with particular reference to certain preferred embodiments thereof, but it will be understood that variations and modifications can be effected within the spirit and scope of the invention.

### PARTS LIST

100 tandem OLED
110 anode
120 EL unit
120.1 1^{st} EL unit
120.2 2^{nd} EL unit
120.N-1) (N-1)^{th} EL unit
120.N N^{th} EL unit
130 connecting unit
130.1 1^{st} connecting unit
130.2 2^{nd} connecting unit
130.(N-1) (N-1)^{th} connecting unit
140 cathode
150 voltage/current source
160 electrical conductors

1. A tandem organic electroluminescent device comprising:
a) an anode;
b) a cathode;
c) a plurality of organic electroluminescent units disposed between the anode and the cathode, wherein each of the organic electroluminescent units includes one or more organic layers including at least a light-emitting layer and an associated light-emitting junction;
d) connecting unit disposed between adjacent organic electroluminescent units; and
e) wherein at least two of the neighboring light-emitting junctions are separated by a distance of less than 90 nanometers.

2. The tandem organic electroluminescent device of claim 1 wherein the anode or the cathode is a reflecting electrode and at least one of the light-emitting junctions in an electroluminescent unit is less than 90 nm from the reflecting electrode.

3. The tandem organic electroluminescent device of claim 1 wherein the output of the tandem organic electroluminescent device is broadband light.

4. The tandem organic electroluminescent device of claim 1 wherein the output of the tandem organic electroluminescent device is narrowband light.

5. The tandem organic electroluminescent device of claim 1 wherein at least one of the organic electroluminescent units emits narrowband light.

6. The tandem organic electroluminescent device of claim 1 wherein at least one of the organic electroluminescent units emits broadband light.

7. The tandem organic electroluminescent device of claim 1 wherein at least one of the organic electroluminescent units emits a different spectrum of light from the other organic electroluminescent units.

8. The tandem organic electroluminescent device of claim 1 wherein at least one of the organic EL units produces blue light or blue-rich light and is located less than 50 nm from an anti-node location of the blue light.

9. The tandem organic electroluminescent device of claim 1 wherein at least one of the organic EL units produces green light or green-rich light and is located less than 50 nm from an anti-node location of the green light.

10. The tandem organic electroluminescent device of claim 1 wherein at least one of the organic EL units produces red light or red-rich light and is located less than 50 nm from an anti-node location of the red light.

11. The tandem organic electroluminescent device of claim 1 wherein two light-emitting units are located near the M=0 anti-node and a third light-emitting unit is located near the M=1 anti-node location.

12. A tandem OLED device including a substrate, a transparent or semi-transparent electrode, a reflecting electrode, a plurality of organic electroluminescent units disposed between the transparent or semitransparent electrode and the reflecting electrode, a connecting unit disposed between adjacent organic electroluminescent units, and a light-extraction enhancement layer disposed between the substrate and the reflecting electrode, wherein each of the organic electroluminescent units includes one or more organic layers including at least a light-emitting layer and an associated light-emitting junction, and wherein the distance between at least two of the neighboring light-emitting junctions is less than 90 nanometers.

13. The tandem OLED device of claim 12 where in the light-extraction enhancement layer is a scattering layer.

14. The tandem OLED device of claim 12 where in the light-extraction enhancement layer is a scattering layer and is optically connected to at least one of the light-emitting layers in the organic EL units.

15. The tandem OLED device of claim 14 where in the scattering layer includes scattering centers dispersed in a matrix.

16. The tandem OLED device of claim 15 wherein the matrix has an optical index smaller that that of the light-emitting layer and at least a fraction of the scattering centers in the scattering layer is located less than one micrometer from the surface of the scattering layer closest to the light-emitting layer.

17. The tandem OLED device of claim 12 where the light-extraction enhancement layer is disposed between the substrate and the transparent or semi-transparent electrode, or between the transparent or semi-transparent electrode and the organic EL units, or between two of the organic EL units, or between the organic units and the reflecting electrode.

18. A tandem OLED device including a substrate, a reflecting electrode, a transparent or semitransparent electrode, a plurality of organic electroluminescent units disposed between the reflecting electrode and the transparent or semitransparent electrode, a connecting unit disposed between adjacent organic electroluminescent units, and a light-extraction enhancement layer disposed over the reflecting electrode, wherein each of the organic electroluminescent units includes one or more organic layers including at least a light-emitting layer and an associated light-emitting junction, and wherein the distance between at least two of the neighboring light-emitting junctions is less than 90 nanometer.

19. The tandem OLED device of claim 18 wherein the light-extraction enhancement layer is a scattering layer.

20. The tandem OLED device of claim 18 wherein the light-extraction enhancement layer is a scattering layer that is optically connected to at least one of the electroluminescent units.

21. The tandem OLED device of claim 20 where in the scattering layer includes scattering centers dispersed in a matrix.

22. The tandem OLED device of claim 21 wherein the matrix has an optical index smaller that that of the light-emitting layer and at least a fraction of the scattering centers in the scattering layer is located less than one micrometer from the surface of the scattering layer closest to the light-emitting layer.

23. The tandem OLED device of claim 18 wherein the light-extraction enhancement layer is disposed between the reflecting electrode and the organic EL units, or between two of the organic EL units, or between the organic units and the transparent or semitransparent electrode, or over the transparent or semitransparent electrode.

24. The tandem OLED device of claim 18 further including a dielectric layer, or a polymer layer, or both, disposed over the transparent or semitransparent electrode.

25. The tandem OLED device of claim 24 wherein the light extraction layer is disposed over the dielectric layer or the polymer layer, or both.

26. The tandem OLED device of claim 18 further including a dielectric layer and a polymer layer over the transparent or semitransparent electrode and wherein the light-extraction enhancement layer is disposed between the dielectric layer and the polymer layer.

27. The tandem OLED device of claim 18 wherein total thickness of all the layers above the reflecting electrode is less than about 0.1 mm.

28. The tandem OLED device of claim 18 further including a coversheet disposed over the transparent or semitransparent electrode.

29. The tandem OLED device of claim 28 further including an optical isolation layer between the coversheet and the light-extraction enhancement layer.

30. The tandem OLED device of claim 29 wherein the optical isolation layer is an air gap.

31. A tandem OLED device including a substrate defining first and second surfaces, an anode and a spaced cathode disposed over the first surface, a plurality of organic electroluminescent units disposed between the anode and the cathode, a connecting unit disposed between adjacent organic electroluminescent units, and a light-extraction enhancement layer disposed over the second surface of the substrate, wherein each of the organic electroluminescent units includes one or more organic layers including at least a light-emitting layer and an associated light-emitting junction, and wherein the distance between at least two of the neighboring light-emitting junctions is less than 90 nanometers.

32. A tandem OLED device of claim 31 wherein the light-extraction enhancement layer is a scattering layer.

33. A tandem OLED device of claim 32 wherein the scattering layer includes a dispersion of scattering centers in a matrix.

34 A tandem OLED device of claim 33 where in the optical index of the matrix is equal to or smaller than that of the substrate and wherein the scattering layer has at least a fraction of the scattering centers located less than one micrometer from interface between the scattering layer and the substrate.
